(19) United States
(12) Patent Application Publication
(10) Pub. No.: US 2006/0095221 A1
(43) Pub. Date: May 4, 2006

(54) Method and apparatus for controlling variable delays in electronic circuitry

(75) Inventors: Jacob Alvin Salmi, Andover, MN (US); Thomas A. Repucci, Blaine, MN (US)

Correspondence Address: TERADYNE, INC.;c/o WOLF, GREENFIELD & SACKS, P.C., FEDERAL RESERVE PLAZA, 600 ATLANTIC AVENUE, BOSTON, MA, 02210-2206, US

(73) Assignee: Teradyne, Inc., Boston, MA (US)

(21) Appl. No.: 10/980,578

(22) Filed: Nov. 3, 2004

(51) Int. Cl. G01R 29/02; G01R 35/00

(52) U.S. Cl. 702/106; 702/79

(57) ABSTRACT

A circuit with delay compensation for variable delays, such as those caused by environmental conditions. A delay compensation element having a delay pattern that matches the delay pattern of the circuit to be compensated is included in the feedback path of a phase locked loop. The delay compensation is described as a programmable delay, which has a rate of change in relation to temperature that varies with the programmed value of the delay. Such a circuit is used in a channel of automatic test equipment. The delay element is incorporated in the feedback path of a phase locked loop used in a clock generation circuit. The structure provides for edge placement accuracies below 250 picoseconds, even if CMOS components are used in the channel.

### BACKGROUND OF INVENTION

1. Field of Invention

This invention relates generally to electronic circuitry and more specifically to improving timing accuracy in electronic circuitry such as test and measurement systems.

2. Discussion of Related Art

Automatic test equipment (sometimes called a “tester”) is widely used in the manufacture of semiconductor devices. The tester may be programmed to generate stimuli signals that are applied to a device under test (DUT). The tester then measures the response to these stimuli signals. By comparing the measured response to an expected response, the tester can determine whether the DUT operates properly. To accurately test the DUT, the tester must reliably generate and measure test signals. In many cases, the time at which the signal is applied to the DUT or is measured at the DUT is important for accurately testing the DUT.

To control the times at which test signals are generated or measured, many testers include timing generators. Timing generators generate “edge” signals. The edge signals trigger circuits to drive or measure test signals. The accuracy with which the tester can generate edges, sometimes called “edge placement accuracy,” limits the ability of the tester to generate or measure test signals at precisely defined times. Accordingly, edge placement accuracy is often a critical specification for a tester. Particularly for testers that are designed to test semiconductor devices operating at relatively high frequencies, it is desirable to have edge placement accuracy as low as possible. For example, it would be desirable for a tester with an edge placement accuracy of less than 250 picoseconds.

FIG. 1A shows a block diagram of a prior art tester 100. Tester 100 includes a controller 112, which may include a general purpose computer or workstation programmed to execute test programs or analyze test results. Controller 112 may also include circuitry that generates timing and synchronization signals for use internal to tester 100. Control signals from controller 112 are routed through fan out circuitry 114 to a plurality of instruments, which are here designated as channels 116₁, 116₂, . . . 116_{N}. Each of the channels 116₁, 116₂ . . . 116_{N} is connected through downstream circuitry 130 to the device under test (DUT) 110.

Various types of instruments may be employed within a tester to generate and measure signals required to fully test various semiconductor devices. FIG. 1A gives an example of instruments that generate and measure digital signals. Taking channel 116₁ as illustrative, the channel is shown to include a clock generator 120. Clock generator 120 generates a digital clock that controls the timing of circuit operations within channel 116₁.

The clock from clock generator 120 is provided to one or more timing generators 122. Each timing generator outputs an edge signal. The timing generators may be programmed to control the timing of each edge signal. In operation, a timing generator 122 counts pulses of the clock generated by clock generator 120 to identify a specific time at which an edge signal may be generated. Some timing generators include “interpolator” circuits that delay the generation of an edge signal for a short time after a specific number of pulses has been counted. Usually this delay includes a fraction of a period of the clock generated by clock generator 120. In this way, the timing of each edge generated by a timing generator 122 can be specified with a high degree of precision.

The edge signals from timing generator 122 are provided to a format circuit 124. Format circuit 124 contains drivers and comparators that operate at times controlled by the edge signals. For example, format circuit 124 may output a pulse with a rising edge that is coincident with a first edge signal and a falling edge that is coincident with a second edge signal. Likewise, format circuit 124 may read a value on a lead connected to DUT 110 at a time specified by an edge signal generated by timing generator 122. Timing generator 122 and format circuit 124 are programmable so that the specific test or measurement function performed by each of the channels can vary from cycle to cycle.

Though timing generator 122 allows the times at which edge signals are generated to be specified with a high degree of precision, such precision only results in accurate timing of test signals if all of the channels are coordinated to the same time reference. To coordinate the activities of multiple channels, each channel generally includes calibration circuitry 126. Calibration circuitry 126 includes a memory that stores calibration values. The calibration values are determined during a calibration routine. As an example, in a simple calibration routine, each channel may be programmed to generate a test signal at the same time. The actual time at which the signal from each channel reaches the interface to DUT 110 is measured. The measured times are used to compute adjustment values that can be used to specify an amount of delay in the faster channels needed to make signals in those channels arrive at the interface to DUT 110 at the same time as signals from the slower channels. By using these adjustment values as an offset to the programmed times in the faster channels, signals from all of the channels 116₁, 116₂ . . . 116_{N} programmed to arrive at DUT 110 at the same time should arrive simultaneously.

If the channels have non-linear delay characteristics, calibration circuitry 126 may store multiple calibration values, one for each programmed time. In this way, calibration is provided for each programmed time at which an edge may be generated. However, calibration circuit 126 generally stores a single set of calibration values. Those calibration values provide accurate edge placement only so long as the delays within tester 100 remain constant. If circuit delays within tester 100 change, the edge placement accuracy of tester 100 may decrease.

We have recognized a particular problem in test systems including circuitry such as clock generator 120. Clock generator 120 includes circuitry that has temperature dependent delay. As the tester heats up or cools down, delays through different channels will change by different amounts and the edge placement accuracy of the tester will decrease.

FIG. 1B is an example of clock generator 120. Clock generator 120 includes a direct digital synthesis (DDS) circuit 150 and a phase locked loop 152. DDS circuit 150 generates a periodic signal having a period that may be controlled through digital controls. The output of DDS 150 is provided to phase locked loop 152. Phase locked loop 152 acts as a frequency multiplier and can generate a clock signal that is some multiple of the frequency of the signal output by DDS circuit 150.

Phase locked loop 152 includes a phase detector 154 and a voltage controlled oscillator 156. The frequency of the signal output by voltage controlled oscillator 156 changes in proportion to the output of phase detector 154.

The output of DDS circuit 150 is provided as one input to phase detector 154. Phase detector 154 receives as a second input the output of frequency scaling circuit 160. Frequency scaling circuit 160 produces an output signal that is lower in frequency than its input by a scale factor. Frequency scaling circuit 160 is in feedback path 158 of phase locked loop 152. The input of frequency scaling circuit 160 is connected to the output voltage controlled oscillator 156. Accordingly, the output of frequency scaling circuit 160 is a signal synchronized to the output of voltage controlled oscillator 156, but reduced in frequency by the scale factor.

Phase detector 154 compares the output of frequency scaling circuit 160 to the output of DDS circuit 150. When the two inputs to phase detector 154 differ, the output of phase detector 154 changes the control input to voltage control oscillator 156. In a properly configured loop, phase detector 154 will adjust its output until voltage controlled oscillator 156 produces an output signal that, when scaled down by frequency scaling circuit 160, matches the output of DDS circuit 150 in frequency and phase. In this way, the output of phase locked loop 152 tracks the output of DDS circuit 150, but is higher in frequency by the scale factor in frequency scaling circuit 160.

In general, all of the channels 116₁, 116₂ . . . 116_{N} receive the same reference clock, REF. Therefore, changes in the reference clock do not change relative timing of events within the channels. Many components within DDS circuit 150 are clocked by a reference clock, REF. However, DDS circuit 150 includes components that are temperature sensitive and produce output values that are not directly tied to the reference clock, REF. For example, a traditional DDS circuit includes a digital-to-analog converter. Further, other components in the signal paths through each of the channels may be temperature sensitive. For example, the timing generators 122 and format circuit 124 may include components that are temperature sensitive. As these components change temperature, the relative timing at which edges are generated may change, reducing the edge placement accuracy of tester 100.

In some prior art test systems, the effects of temperature sensitive components were reduced by controlling the temperature of all of the components within a test system. For example, cold plates can be placed over electronic circuits. The cold plates act as heat sinks that tend to keep all of the components within the tester at the same operating temperature. However, it would be desirable to provide greater edge placement accuracy within a tester or more generally greater timing accuracy in any electronic circuitry.

### SUMMARY OF INVENTION

In one aspect, the invention relates to a delay compensated electronic system that has a first circuit having a delay dependency on at least one environmental variable; a second circuit having a feedback path, the second circuit connected in series with the first circuit; and a delay compensation element connected in the feedback path having a delay dependency proportional to the delay dependency of the first circuit.

In another aspect, the invention relates to an automatic test system having a plurality of channels. Each channel has at least one first circuit having a first delay that changes in response to temperature with a first pattern; a phase locked loop having a feedback path coupled to the at least one first circuit; and a delay element having a delay that changes in response to temperature with the first pattern, the delay element connected in the feedback path.

In yet another aspect, the invention relates to a method of operating a circuit having one or more sub-circuits that have a delay that changes in response to environmental conditions with a first pattern. The method involves providing a delay element in a feedback path in the circuit, the delay element having a delay that changes in response to environmental conditions with the first pattern and operating the circuit.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1A is a block diagram of a prior art test system;

FIG. 1B is a block diagram of a prior art clock generation circuit;

FIG. 2 is a block diagram of an improved clock generation circuit;

FIG. 3 is a graph useful in understanding the operation of delay element 210 in FIG. 2; and

FIG. 4 is a flow chart of a process by which a tester employing the improved clock generation circuit of FIG. 2 may be operated.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The delay compensation system described below offers several advantages. We have recognized that a significant cause of inaccuracy in edge placement is variation in the delays within the channels of the tester. The delay within the circuitry of the channels may change based on environmental conditions, such as temperature.

Circuits made with certain types of technologies are more susceptible to delay variations then others. For example, CMOS circuitry is particularly susceptible to delay variations. CMOS circuitry is widely available, low cost, low power and relatively compact. It therefore presents many desirable attributes for use in a test system. It would be desirable to use CMOS components in a tester, even the timing system of a tester, without an unacceptable decrease in edge placement accuracy.

We have further recognized that variable delays within the clock generation or timing circuitry of the tester are particularly detrimental to edge placement accuracy.

To avoid these problems, we have developed a delay compensation method and associated circuitry. This delay compensation method and circuitry may be used within the timing system, and particularly the clock generation circuitry in a tester. It is also suitable for use with CMOS components.

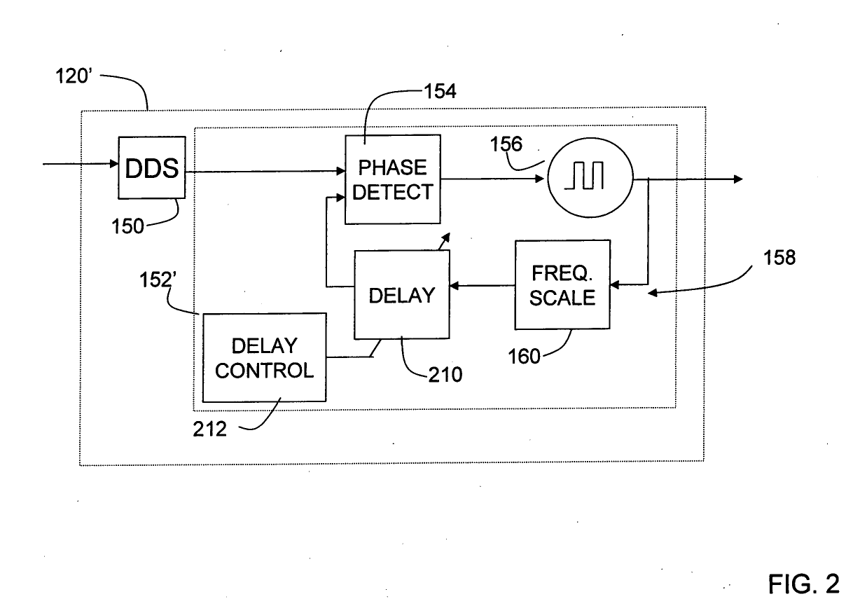

FIG. 2 shows a modification to clock generator 120 that compensates for variable delays. Clock generator 120′ may include a DDS circuit 150 similar to the DDS circuit used in clock generator 120 of the prior art. The output of DDS circuit 150 is provided to a phase locked loop 152′. Phase locked loop 152′ serves the same function as phase locked loop 152 in the prior art, but includes delay compensation circuitry. As in the prior art, phase lock loop 152′ includes a phase detector 154, a voltage controlled oscillator 156 and a feedback path 158 that includes frequency scaling circuit 160. In addition, phase locked loop 152′ includes a variable delay 210 connected in feedback path 158 and a delay control circuit 212.

Variable delay 210 has delay characteristics that preferably match the delay characteristics of the circuitry for which delay compensation is to be provided. For example, if DDS circuit 150 has a delay that increases 1 picosecond per degree C. of temperature increase, variable delay 210 will have a similar delay characteristic, increasing by 1 picosecond per degree C. of temperature increase.

Because the variable delay 210 is connected in a feedback path 158, any delay introduced by variable delay circuit 210 has the effect of advancing the phase of the signal out of phase lock loop 152′. With this arrangement, any delay introduced by variable delay element 210 is effectively subtracted from the output of phase locked loop 152′. When phase locked loop 152′ is connected in series with another element that introduces delay, the delay effectively subtracted by phase locked loop 152′ offsets the delay introduced by the other elements in series with phase locked loop 152′.

For example, if variable delay 210 and DDS circuit 150 have the same delay characteristics for change in delay with respect to temperature, the delays through DDS circuit 150 and variable delay 210 should change by the same amount as the temperature of operation of clock generator 120′ changes. Any temperature induced “drift” in the delay through DDS circuit 150 is offset by changes in the delays introduced by variable delay 210. In this way, variable delay 210 acts as a delay compensation element and the timing of the outputs of clock generator 120′ remains relatively constant even as the operating temperature of the circuit changes.

Variable delay 210 may be a commercially available semiconductor component. Programmable delay lines such as Part Number MC100EP195 purchased from OnSemi may be used. The specific circuit used preferably has a delay characteristic that matches the delay characteristic of the components for which delay compensation is required. Generally, the programmable delay 210 will be made with the same technology as the components for which compensation is desired. For example, if temperature related changes in delay are introduced through DDS circuit 150 because of a CMOS digital-to-analog converter, variable delay 210 may be a CMOS component. However, any delay compensation element that has delay characteristics similar to CMOS can be used to provide delay compensation for a CMOS component.

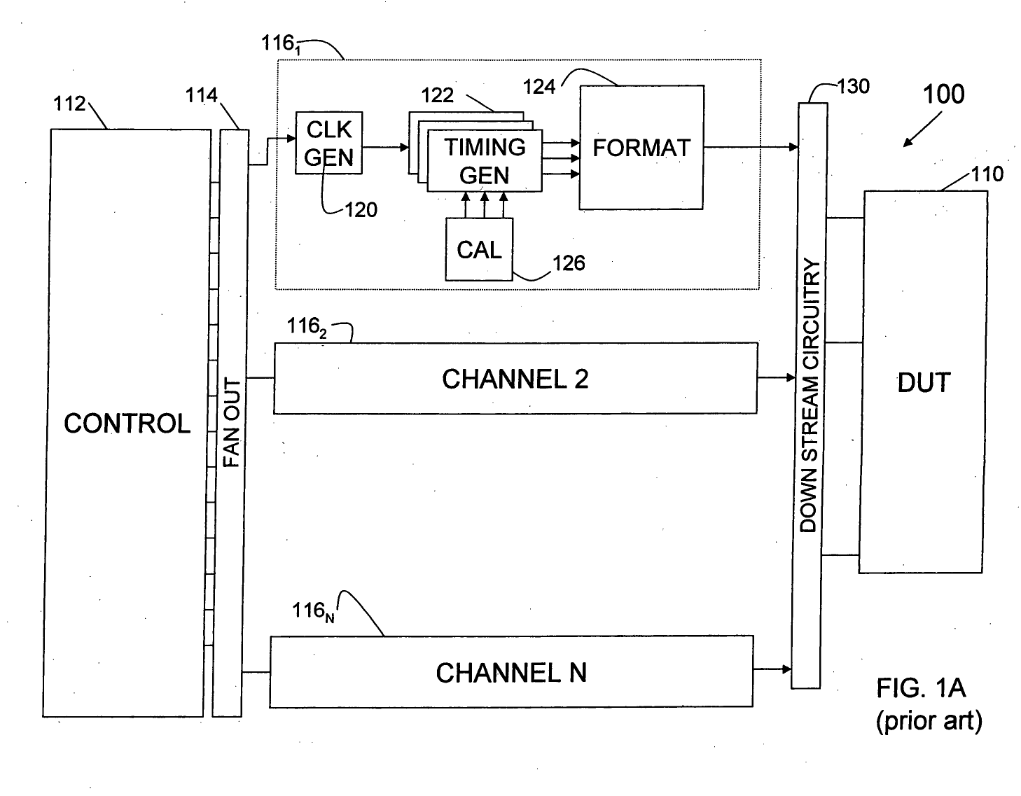

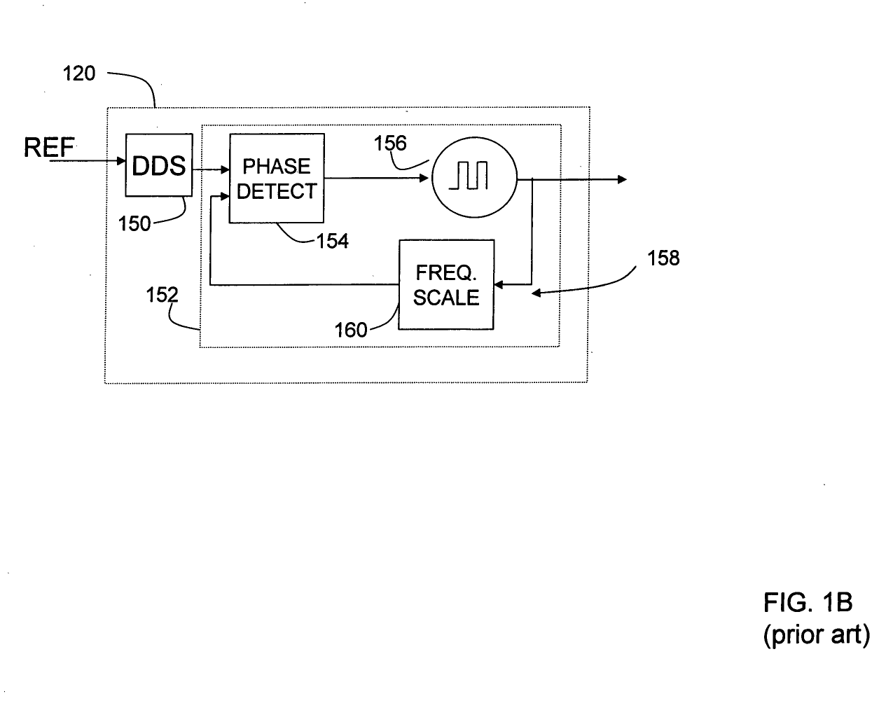

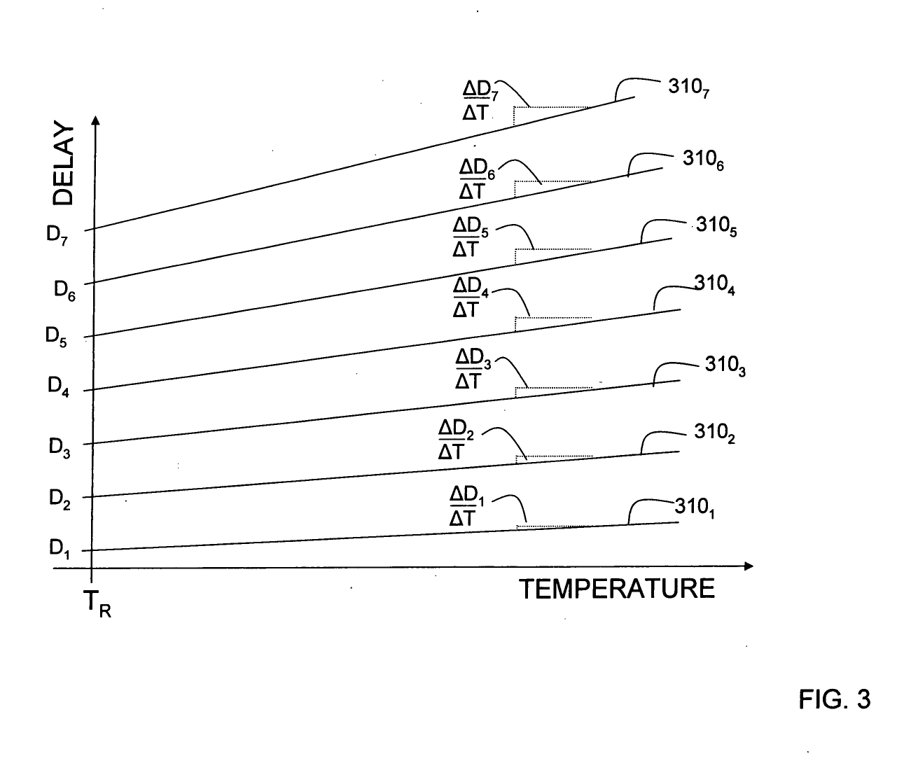

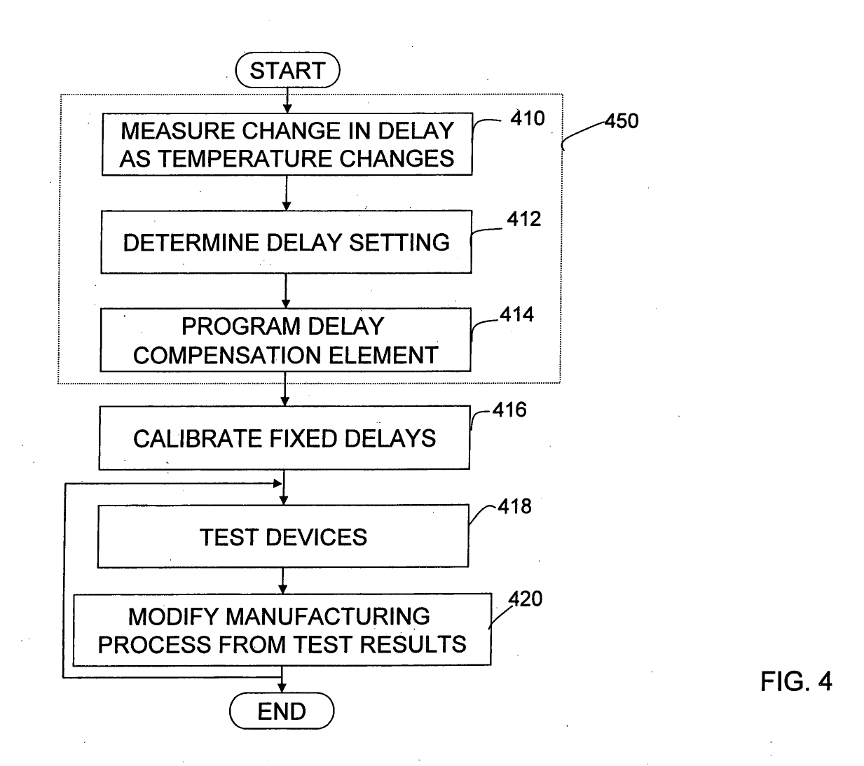

Delay control 212 provides control inputs to variable delay 210. The control inputs are selected to cause variable delay 210 to have the desired delay characteristics. In an embodiment where variable delay 210 receives digital inputs that control the delay, delay control 212 may be a register holding a digital value. Selection of the appropriate control values for delay control 212 is described below in connection with FIGS. 3 and 4. If delay control 212 is a register, a value may be loaded into delay control 212 from controller 112 (FIG. 1A). By implementing delay control 212 as a digital register, the control values for variable delay 210 may be changed dynamically as the tester is used. Where dynamic control is contemplated, the performance of the circuit for which delay is compensated by variable delay 210 may be occasionally measured and new delay values computed and stored in delay control 212. For example, new values may be computed and stored in delay control 212 once a day.

However, delay characteristics of circuitry may not change by a large enough amount as a tester is in routine use to warrant dynamic updating of the control values. While the specific delays through a circuit may change as environmental conditions change, the characteristics of those changes will likely remain relatively constant. Therefore, embodiments may be constructed in which delay control 212 is set when a tester is manufactured. Delay values could be updated as part of servicing of instruments containing variable delay 210, but would not be changed dynamically as the tester operates. In this scenario, delay control 212 could be a relatively permanent form of storage. For example, delay control 212 could be a flash memory. Alternatively, delay control 212 could be implemented as switches, jumpers, hard wiring, or other relatively permanent or semi-permanent connections.

Variable delay 210 can act as a delay compensation element for a wide range of components because it has delay characteristics that can be altered to match the delay characteristics of other components in the circuit. FIG. 3 illustrates how a variable delay can be used for this purpose. FIG. 3 shows a delay versus temperature pattern for a programmable delay. Multiple curves 310₁, 310₂ . . . 310₇ are shown. Each of the curves represents the delay versus temperature pattern of the device when programmed for a different delay setting. Taking curve 310₁ as illustrative, this curve corresponds to the delay produced with a setting D₁.

At a reference temperature, T_{R}, the delay through variable delay 210 corresponds to D₁. As the temperature increases, curve 310₁ slopes upward, indicating an increase in delay. Over the operating range of interest, this increase is generally linear. Accordingly, curve 310₁ indicates a delay characteristic that is relatively constant, having a delay characteristic that may be represented as

$$\frac{Δ {D}_{1}}{Δ T} .$$

Curve 3102 represents the delay pattern for the programmable delay when the delay value is set to D₂. As with curve 310₁, 310₂ is generally linear. Curve 310₂ shows a higher fixed delay at the reference temperature, T_{R}. It also shows a constant change in delay with respect to temperature represented by

$$\frac{Δ {D}_{2}}{Δ T} .$$

In the illustrated example,

$$\frac{Δ {D}_{2}}{Δ T}$$

is greater than

$$\frac{Δ {D}_{1}}{Δ T} .$$

The delay of variable delay 210 follows the same pattern for other delay settings. For delay settings such as D₃ . . . D₇, variable delay 210 has a constant change in delay with respect to temperature. However, for larger programmed delay values, the change in delay with respect to temperature is greater.

Once the desired delay characteristics of the circuit for which compensation is desired are identified, variable delay 210 may be set with the delay value that has matching delay characteristics. For example, if over the temperature range of interest DDS circuit 150 has a constant delay change per degree C. matching the value of

$$\frac{Δ {D}_{4}}{Δ T} ,$$

variable delay 210 could be programmed with the delay value of D₄. In this way, the change in the delay through delay element 210 would match the change in delay of DDS circuit 150 as the operating temperature of clock generator 120′ changed.

Setting the delay value of variable delay 210—in addition to providing the desired delay characteristic—introduces a fixed delay through clock generator 120′. The amount of fixed delay introduced in each of the clock generators may vary from channel to channel. Such variation in delays could prevent events in the channels from being coordinated. However, as described above in connection with FIG. 1A, testers have traditionally included calibration circuitry such as 126 that calibrates out fixed delays between the channels. Preferably, calibration circuitry 126 will be set after the variable delays 210 are programmed in all of the channels including delay compensation circuitry.

FIG. 4 shows a process by which a tester such as tester 100 including a clock generation module 120′ may be used in the manufacture of semiconductor devices. The process begins at block 410 where measurements are made to indicate the change in delay with respect to temperature. Such a measurement could be made by programming clock generation circuit 120′ to generate a clock at a fixed frequency. The output of clock generation circuit 120′ would then be observed as the temperature of the components making up clock generation circuit 120′ is changed. The output of the clock generation circuit 120′ would be compared to a reference clock not subject to temperature variations. In this way, changes in the time of pulses of clock generator 120′ may be identified.

Various ways could be used to change the temperature of the circuitry of interest. For example, when the components of interest are attached to a printed circuit board that has a cold plate with fluid running through it, the temperature of the fluid could be adjusted to create a corresponding change in temperature of the components. Alternatively, a heating or cooling element could be applied only to the components of interest.

It is not necessary that clock generator 120′ be installed in a test system when programmable delay 210 is set. A printed circuit board on which clock generator 120′ is constructed could be removed from the tester and placed in an oven or other temperature controlled chamber for measuring changes in delay induced by temperature changes.

At block 412 a delay setting for programmable delay 210 that offsets the change in temperature measured at block 410 is determined. The change in delay with respect to temperature, determined at block 410, may be compared to the characteristics of the programmable delay element 210 as shown in FIG. 3. The delay setting that provides the closest match to the measured delay change can be selected. Alternatively, where the delay characteristics of variable delay 210 are not known, an appropriate delay setting could be selected in an iterative fashion. In this embodiment, the delay setting of variable delay 210 is changed and the measurement of block 410 repeated. The process of adjusting the variable delay and measuring the output of the circuit to be compensated is repeated until a delay setting resulting in little or no change in delay with respect to temperature is detected.

Once the appropriate delay setting for programmable delay 210 is determined, processing proceeds to block 414. At block 414, the determined value is programmed into delay control 212. The specific programming steps may vary based on the implementation of delay control 212. The appropriate control values may be recorded in a flash memory or other nonvolatile memory. Alternatively, they may be recorded on a disk or other storage media associated with a computer within controller 112. Where switches are used to implement delay control 212, the switches would be set at block 414.

Where multiple clock generators for which delay compensation is desired are included in a tester, sub-process 450 is performed on each clock generator 120′ within tester 100. The delay compensation element for each clock generator may be set independently. For example, the delay compensation elements could be programmed on circuit boards before they are installed in a tester.

Accordingly, sub-process 450 may occur during the manufacture of tester 100. Because programming the delay compensation elements can potentially introduce fixed delay from channel to channel in a tester, the process proceeds to block 416. At block 416, the clock generators as assembled in a tester are calibrated to remove the effects of fixed timing differences among the channels. Block 416 may represent a calibration routine such as is known in the art, resulting in calibration values stored in calibration circuitry 126.

Once the tester is calibrated for both delay variation and fixed delays, the process proceeds to block 418. At block 418, the tester may be used to test semiconductor devices. Testing may be performed generally as in the prior art. However, the tester may test devices with much greater edge placement accuracy. Tests may be performed at block 418 with edge placement accuracies below 250 picoseconds.

At block 420, the semiconductor manufacturing process is modified based on test results collected in block 418. The results of tests on an individual semiconductor device may indicate a fault within that device. Where the fault renders the device completely inoperable, the device may be rejected. Some semiconductor devices are constructed with redundant elements and can be repaired by removing a defective element and substituting a redundant element. Thus, one way the manufacturing process can be altered is to subject the semiconductor device to a laser repair or similar operation to substitute a redundant element for a faulty element. In other cases, test results indicate that a device, though faulty, performs according to a degraded specification. In such a situation, the manufacturing process may be altered by binning the tested device for a lower performance. Devices binned as lower performance devices may be packaged and/or labeled as devices with lower performance specifications and sold for a lower price. Alternatively, where test results indicate a device has no faults, the device may be passed through to the next stage of the manufacturing operation.

Test results from multiple semiconductor devices could alternatively be combined to identify needed adjustments in the parameters of the manufacturing equipment used to make the devices. For example, statistical analysis on test results from a batch of devices may indicate misalignment in a wafer stepper which could be corrected. Blocks 418 and 420 may be repeated iteratively as many devices are tested.

Having thus described several aspects of at least one embodiment of this invention, it is to be appreciated various alterations, modifications, and improvements will readily occur to those skilled in the art.

For example, it was described above that a variable delay element is used as a delay compensation element. Using a variable delay provides a convenient way to change the delay pattern of the device. The fixed delay introduced by that element is preferably made irrelevant by a calibration step such as shown in block 416. Accordingly, it is not necessary that the delay compensation element be a variable delay. A delay compensation element may be constructed in any convenient manner that results in a circuit having delay characteristics comparable to the delay characteristics of a circuit for which compensation is desired. One alternative for providing the required change in delay with respect to temperature is to insert a component having the desired delay characteristic.

Also, it was described that delay compensation is provided for temperature drift. However, other environmental factors besides temperature may impact the delay in the circuit. Compensation may be provided for changes caused by other environmental variables by providing a delay compensation element that responds to those environmental variables in the same way that the components for which calibration is desired. As used herein the term “environmental variable” includes a factor that can alter the manner in which a circuit operates. Temperature is one environmental variable. In some cases, relative humidity may impact operation of a circuit and may therefore be considered an environmental variable. As another example, the operation of a circuit may change over time as it operates, such that time of operation could be considered an environmental variable.

Further, the invention was illustrated with an example in which delay changes within DDS circuit are compensated. Each of the channels 116₁ . . . 116_{N} includes multiple components in the signal path to DUT 110. Any of these components may have delay characteristics for which compensation is desired. Where compensation is desired for more than one component, the delay compensation element should be set with a delay that matches the net delay characteristics for all of the circuits in the signal path for which compensation is desired.

As a further example of possible variations, phase locked loops are often characterized based on the order of the phase detector used in the loop. The term “phase locked loop” is sometimes used only in connection with phase locked loops having a second order phase detector. Phase locked loops with detectors of other orders are sometimes given different names, such as “delay locked loop.” As used herein, the term phase locked loop refers to any similar structure regardless of the order of the phase detector and phase locked loops with any order phase detector may be used.

As a further alternative, a delay compensation element inserted in the feedback path of a phase locked loop is shown. A delay compensation element may be inserted in any convenient feedback path.

As yet another example, FIG. 1A shows a tester 100 with a clock generator per channel. A tester may be implemented with digital instruments. Each digital instrument may contain circuitry for multiple channels, but only one clock generator.

Further, the above described system has one delay compensation setting for each variable delay 210. This same value is used regardless of the operating temperature of the circuitry to be compensated. Such an approach is suitable in the described embodiments in which the change in delay as a function of temperature of both the delay compensation element and the circuit to be compensated are constant over the operating temperature range. If either the circuit to be compensated or the delay compensation element have non-linear delay characteristics, it may be desirable to compute multiple control values suitable for different operating conditions. In this case, tester 100 may include a sensor to detect the operating condition and, in response, load a value associated with that operating condition in delay control 212. Alternatively, if the circuit to be compensated has delay changes with respect to an environmental condition that are not constant, a different type of delay compensation element may be employed to provide a delay characteristic that matches the circuit to be calibrated.

Such alterations, modifications, and improvements are intended to be part of this disclosure, and are intended to be within the spirit and scope of the invention. Accordingly, the foregoing description and drawings are by way of example only.

What is claimed is:

1. A delay compensated electronic system comprising:
a) a first circuit having a delay dependency on at least one environmental variable;
b) a second circuit having a feedback path, the second circuit connected in series with the first circuit; and
c) a delay compensation element connected in the feedback path having a delay dependency proportional to the delay dependency of the first circuit.

2. The delay compensated electronic system of claim 1 wherein the delay compensation element comprises a programmable delay circuit.

3. The delay compensated electronic system of claim 2 wherein the programmable delay of the delay compensation element is programmed with a value to yield a rate of change of delay with respect to temperature comparable to the delay dependency of the first circuit.

4. The delay compensated electronic system of claim 1 wherein the delay dependency of the first circuit is a change of delay with respect to temperature and the delay of the delay compensation element has a corresponding change of delay with respect to temperature.

5. The delay compensated electronic system of claim 4 wherein the second circuit comprises a phase locked loop.

6. The delay compensated electronic system of claim 5 wherein the phase locked loop comprises a voltage controlled oscillator and a phase detector and a feedback path between the voltage controlled oscillator and the phase detector and the delay compensation element is connected in the path between the voltage controlled oscillator and the phase detector.

7. The delay compensated electronic system of claim 6 wherein the first circuit comprises a DDS circuit.

8. The delay compensated electronic system of claim 7 wherein the DDS circuit comprises a CMOS digital to analog converter.

9. The delay compensated electronic system of claim 1 wherein the first circuit comprises CMOS circuitry having a delay that varies with temperature.

10. An automatic test system having a plurality of channels, each channel comprising:
a) at least one first circuit having a first delay that changes in response to temperature with a first pattern;
b) a phase locked loop having a feedback path coupled to the at least one first circuit; and
c) a delay element having a delay that changes in response to temperature with the first pattern, the delay element connected in the feedback path.

11. The automatic test system of claim 10 wherein the phase locked loop comprises a second order phase detector.

12. The automatic test system of claim 11 wherein the at least one first circuit comprises a digital to analog converter.

13. The automatic test system of claim 10 wherein each channel comprises a clock generator and the at least one first circuit and the phase locked loop are portions of the clock generator.

14. The automatic test system of claim 10 wherein each channel comprises calibration circuitry.

15. The automatic test system of claim 10 wherein the at least one first circuit comprises a digital to analog converter.

16. The automatic test system of claim 15 wherein the digital to analog converter comprises a CMOS digital to analog converter.

17. The automatic test system of claim 16 wherein the delay element comprises a programmable CMOS delay element.

18. The automatic test system of claim 10 wherein the delay element comprises a programmable delay element.

19. A method of operating a circuit having one or more sub-circuits that have a delay that changes in response to environmental conditions with a first pattern, comprising:
a) providing a delay element in a feedback path in the circuit, the delay element having a delay that changes in response to environmental conditions with the first pattern; and
b) operating the circuit.

20. The method of operating a circuit of claim 19 wherein the circuit is in a channel of an automatic test system.

21. The method of operating a circuit of claim 20 wherein providing a delay element comprises:
a) providing a programmable delay element;
b) setting the programmed delay value of the delay element;
c) after the programmed delay value of the delay element is set, calibrating for fixed delay in the tester channel.

22. A method of manufacturing semiconductor devices using the method of claim 21, wherein operating the circuit comprises performing a test on at least one semiconductor device during its manufacture and the method further comprises making a change in the manufacturing process as a result of the result of the test.

23. The method of manufacturing semiconductor devices of claim 22 wherein the first pattern is a rate of change of delay with respect to temperature and providing a delay element having a delay that changes in response to environmental conditions with the first pattern comprises providing a delay element that has a rate of change of delay with respect to temperature matching the first pattern.

24. The method of claim 19 wherein the providing a delay element comprises providing a variable delay with the delay set to have a change in delay as a function of temperature that matches the first pattern.

25. The method of claim 24 wherein the circuit is a channel of an automatic test system having a plurality of channels, the method additionally comprising calibrating the automatic test system for differences in fixed delay between the channels.

26. The method of operating a circuit of claim 19 wherein the one or more sub-circuits comprise a DDS circuit.

27. The method of claim 26 wherein operating the circuit comprises generating a stable clock signal.
